(19) United States
(12) Patent Application Publication
(10) Pub. No.: US 2014/0329454 A1
(43) Pub. Date: Nov. 6, 2014

(54) SERVER CABINET AND AIR BLOCKING DEVICE OF THE SAME

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: AN-GANG LIANG, Shenzhen (CN); MING-YU LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/144,404

(22) Filed: Dec. 30, 2013

(30) Foreign Application Priority Data
May 2, 2013 (CN) 2013101569528

(51) Int. Cl. H05K 5/02; H05K 7/20

(52) U.S. Cl. CPC H05K 5/0213; H05K 7/20
USPC 454/184; 211/180

(57) ABSTRACT

A server cabinet includes a cabinet body and an air blocking device. The air blocking device includes a frame and a foam body installed on the frame. The frame defines an opening. The foam body includes a first foam body and a second foam body connected with the first foam body. The junction of the first foam body and the second foam body is surrounded by the opening.

### BACKGROUND

1. Technical Field

The present disclosure relates to server cabinets and, particularly, to a server cabinet having an air blocking device.

2. Description of Related Art

A server cabinet is usually equipped with several air baffles in the open area without a server being installed to avoid inverse air flow, to ensure the heat dissipation effect of the server cabinet. When the connectors of the switches and the connection interface of the server are not on the same side, the air baffle needs to be removed to allow room for the cables, which will cause air leakage.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a server cabinet, wherein the server cabinet comprises an air blocking device.

FIG. 2 is an assembled, isometric view of FIG. 1.

FIG. 3 is an exploded, isometric view of the air blocking device of FIG. 1, but viewed from another perspective.

FIG. 4 is an enlarged view of the circled portion IV of FIG. 3.

FIG. 5 is similar to FIG. 2, showing the air blocking device in use.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

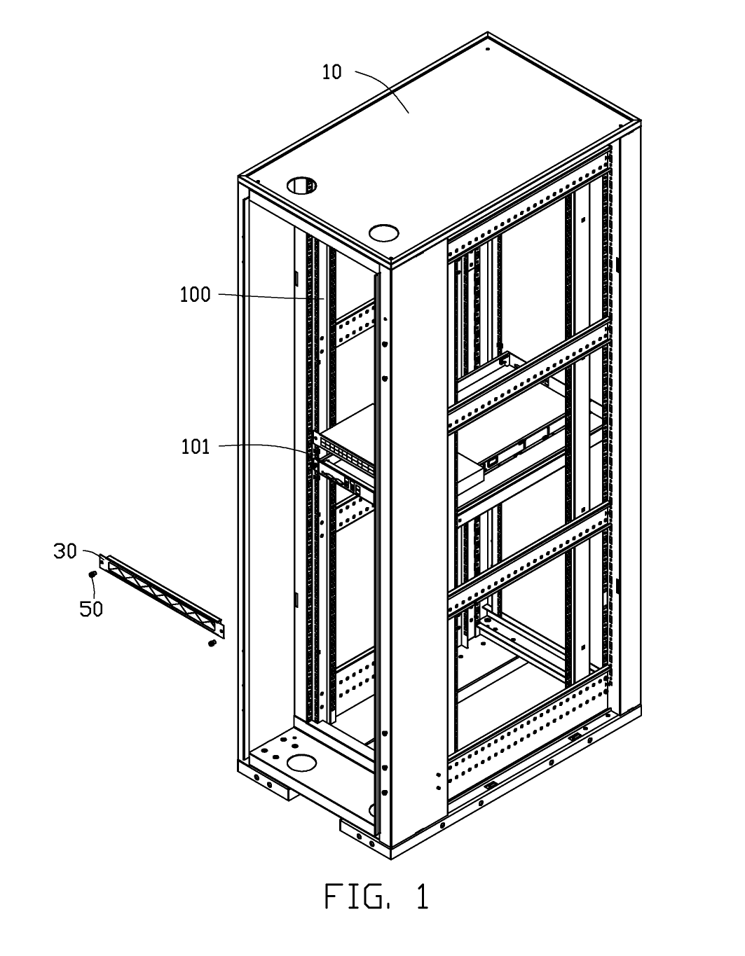

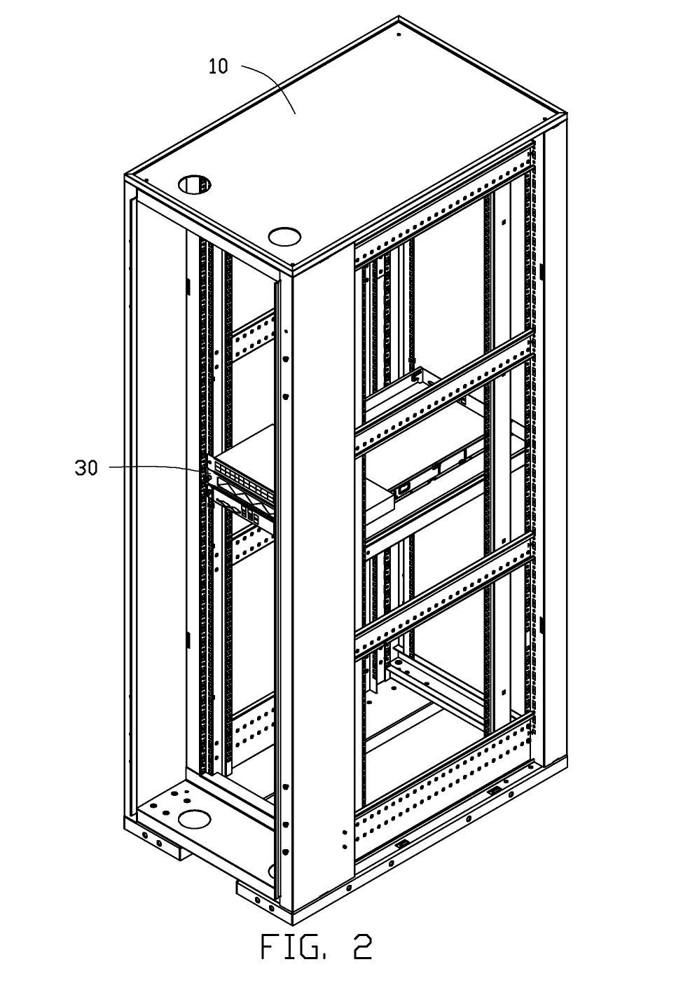

FIG. 1 and FIG. 2 show an exemplary embodiment of a server cabinet. The server cabinet comprises a cabinet 10, an air blocking device 30 and two screws 50. The cabinet 10 comprises four upright supporting poles 100. Each supporting poles 100 longitudinally defines a plurality of equidistant spacing screw holes 101.

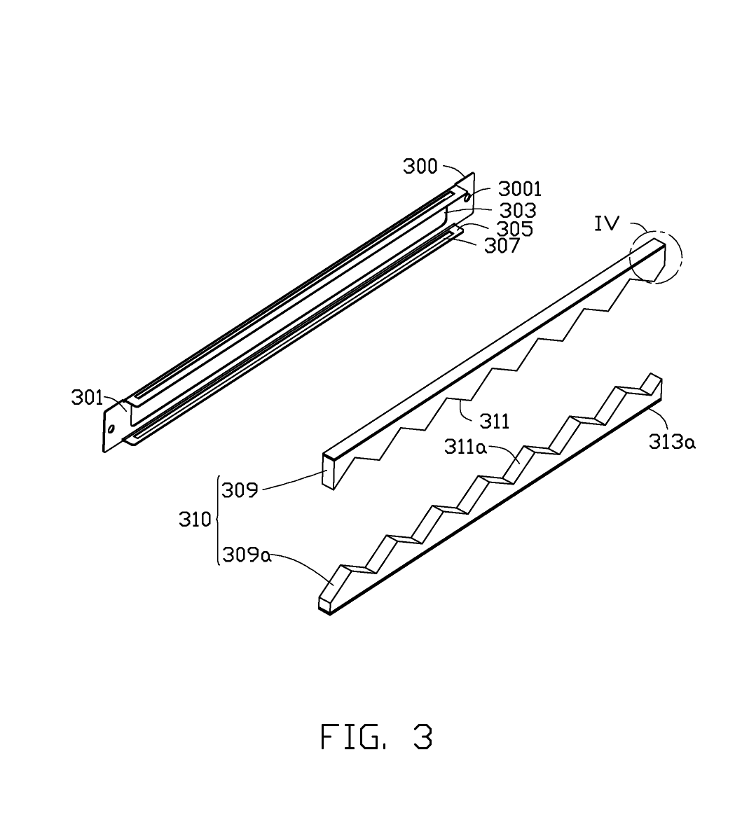

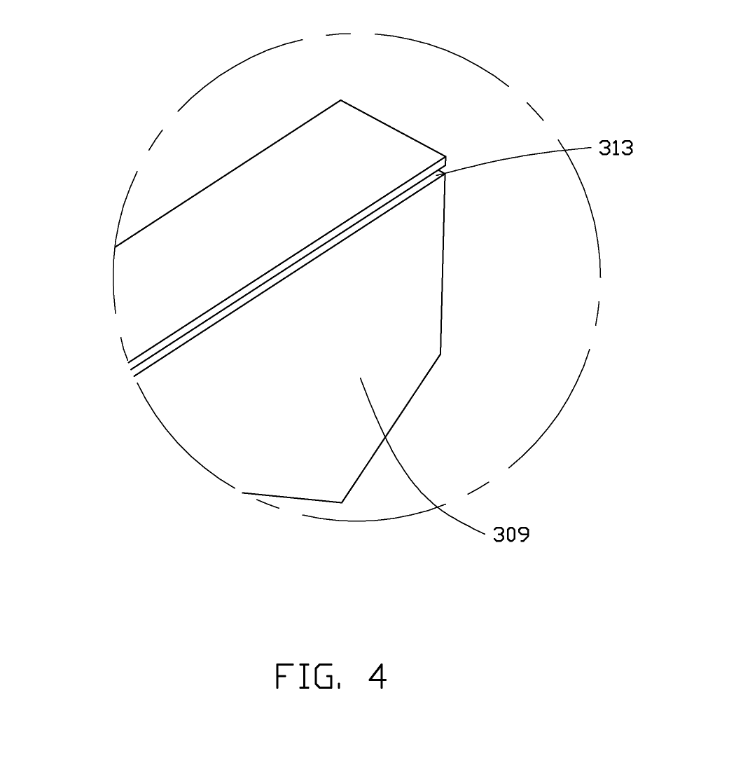

FIG. 3 and FIG. 4 show that the air blocking device 30 comprises a frame 300 and a foam body 310 installed on the frame 300. The frame 300 comprises a substantially rectangular main plate 301 and two substantially rectangular flanges 305 perpendicularly extending from the top and bottom sides of the main plate 301. Each flange 305 longitudinally defines a substantially rectangular mounting hole 307. The main plate 301 longitudinally defines a substantially rectangular opening 303, and defines two through holes 3001 at opposite side ends of the opening 303.

The foam body 310 comprises a first foam body 309 and a second foam body 309a. The first foam body 309 comprises a first sawtooth portion 311 at the bottom side of the first foam body 309, and longitudinally defines a limiting slot 313 surrounding the top side of the first foam body 309. The second foam body 309a comprises a second sawtooth portion 311a at the top side of the second foam body 309a, which is corresponding to the first sawtooth portion 311. The second foam body 309a longitudinally defines a limiting slot 313a surrounding the bottom side of the second foam body 309a.

In assembly, the first foam body 309 is deformed to allow the top side of the first foam body 309 to extend through the mounting hole 307 of the top flange 305 from a bottom of the top flange 305, and the second foam body 309a is deformed to allow the bottom side of the second foam body 309a to extend through the mounting hole 307 of the bottom flange 305 from a top of the bottom flange 305. Therefore, edges bounding the mounting holes 307 are engaged in the corresponding limiting slots 313 and 313a, to mount the first and second foam body 309 and 309a to the frame 300. The first sawtooth portion 311 of the first foam body 309 meshes with the second sawtooth portion 311a of the second foam body 309a. A junction 310 between the first and second sawtooth portions 311 and 311a is surrounded by the opening 303. The screws 50 extend through the through holes 3001 and screw in the screw holes 101 in a same height, to fix the air blocking device 30 between two adjacent upright supporting poles 100 of the cabinet 10.

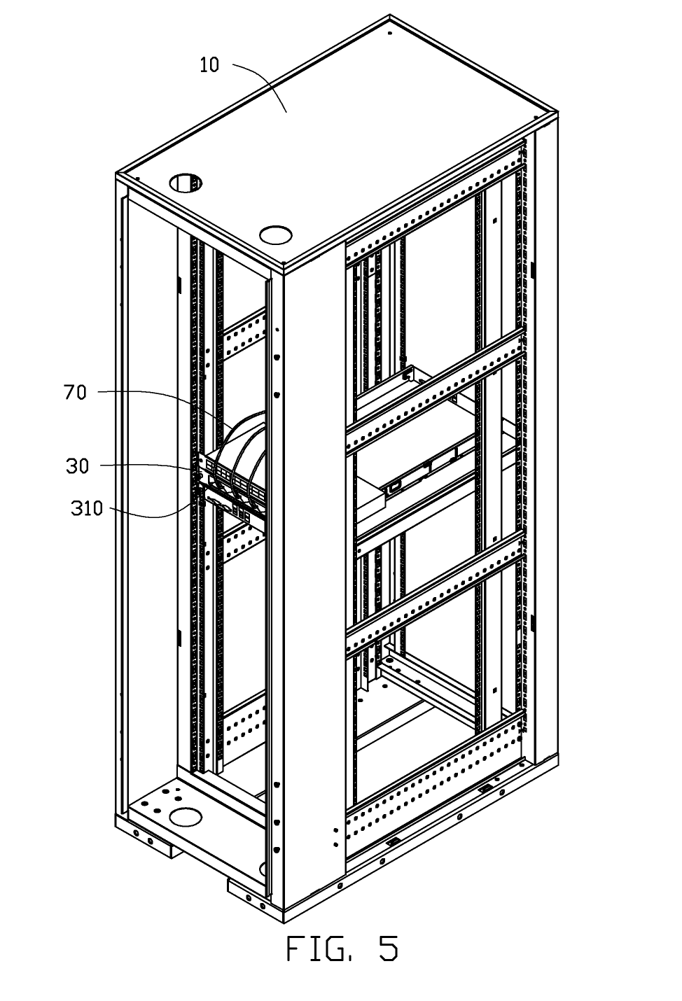

FIG. 5 shows that, cables 70 are extended through the opening 303 and the foam body 310, to be sandwiched between the first and second foam bodies 309 and 309a, to avoid air leakage.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An air blocking device, comprising:
a frame defining an opening; and
a foam body installed to the frame, and comprising a first foam body and a second foam body meshing with the first foam body, wherein a junction of the first foam body and the second foam body is surrounded by the opening.

2. The air blocking device of claim 1, wherein the frame comprises a main plate and two flanges extending from opposite sides of the main plate, the opening is longitudinally defined in the main plate, and the first foam body and the second foam body are respectively mounted to the two flanges.

3. The air blocking device of claim 2, wherein each flange longitudinally defines a mounting hole, a top side of the first foam body and a bottom side of the second foam body define two limiting slots, edges bounding the mounting holes of flanges are engaged in the corresponding limiting slots.

4. The air blocking device of claim 3, wherein the limiting slots respectively surround the top side of the first foam body and the bottom side of the second foam body.

5. The air blocking device of claim 4, wherein the first foam body comprises a first sawtooth portion at a bottom side, and the second foam body comprises a second sawtooth portion at a top side, the first sawtooth portion meshes with the second sawtooth portion, the opening faces a junction of the first sawtooth portion and the second sawtooth portion.

6. The air blocking device of claim 2, wherein the main plate defines two through holes at two ends of the opening.

7. A server cabinet comprising:
a cabinet; and
an air blocking device comprising a frame and a foam body installed to the frame, wherein the frame defines an opening, the foam body comprises a first foam body and a second foam body meshing with the first foam body, and the junction of the first foam body and the second foam body is surrounded by the opening.

8. The server cabinet of claim 7, wherein the frame comprises a main plate and two flanges respectively extending from top and bottom sides of the main body, the opening is defined in the main plate, and the first foam body and the second foam body are respectively mounted to the flanges.

9. The server cabinet of claim 8, wherein each flange defines a mounting hole, a top side of the first foam body and a bottom side of the second foam body each define a limiting slot, edges bounding the mounting holes of the flanges are engaged in the corresponding limiting slots of the top side of the first foam body and the bottom side of the second foam body.

10. The server cabinet of claim 9, wherein the first foam body comprises a first sawtooth portion at a bottom side, and the second foam body comprises a second sawtooth portion at a top side, the first sawtooth portion meshes with the second sawtooth body, the opening faces a junction of the first sawtooth portion and the second sawtooth portion.
